(19) United States
(12) Patent Application Publication
(10) Pub. No.: US 2025/0379066 A1
(43) Pub. Date: Dec. 11, 2025

(54) SYSTEMS AND METHODS FOR REDUCING GAPS AROUND SURFACE MOUNT DEVICES IN STACKED SEMICONDUCTOR DEVICES

(71) Applicant: Micron Technology, Inc., Boise, ID (US)

(72) Inventors: Chen Hsieng Lee, Singapore (SG); Yeow Chon Ong, Singapore (SG)

(21) Appl. No.: 19/217,954

(22) Filed: May 23, 2025

Related U.S. Application Data
(60) Provisional application No. 63/656,773, filed on Jun. 6, 2024.

(51) Int. Cl. H01L 21/56; H01L 23/31

(52) U.S. Cl. CPC H01L 21/56; H01L 23/3135

(57) ABSTRACT

Systems and methods for manufacturing semiconductor packages are disclosed herein. In some embodiments, the method includes integrating one or more capacitors and a stack of one or more semiconductor dies with an upper surface of a base substrate of the semiconductor package. The method also includes encasing each of the one or more capacitors with a first encapsulant, then depositing a second encapsulant over each of the one or more capacitors and the die stack. The first encapsulant can have a first individual particle size that is smaller than a second individual particle size of the second encapsulant. The relatively small particle size allows the first encapsulant to completely fill spaces between the capacitors and the base substrate and/or fully adhere to the surfaces of the capacitors. As a result, the first encapsulant can reduce voids in the completed semiconductor package that can cause deleterious effects.

### CROSS-REFERENCE TO RELATED APPLICATION(S)

The present application claims priority to U.S. Provisional Patent Application No. 63/656,773, filed Jun. 6, 2024, the disclosure of which is incorporated herein by reference in its entirety.

### TECHNICAL FIELD

The present technology is generally directed to surface mount devices in semiconductor assemblies and more specifically to systems and methods for reducing mold voids around capacitors in semiconductor assemblies.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) can utilize electrical energy to store and access data.

With technological advancements in embedded systems and increasing applications, the market is continuously looking for faster, more efficient, and smaller devices. To meet market demands, semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet market demands, such as by reducing the overall device footprint, can often introduce challenges in other aspects, such as maintaining circuit robustness and/or failure detectability.

### BRIEF DESCRIPTION OF THE DRAWINGS

FIGS. 1A and 1B are partially schematic cross-sectional views of a semiconductor package.

FIGS. 2A and 2B are partially schematic cross-sectional views of a semiconductor package configured in accordance with some embodiments of the present technology.

FIG. 3 is a flow diagram of a process for manufacturing a semiconductor package in accordance with some embodiments of the present technology.

FIGS. 4A-4F are partially schematic cross-sectional views of a semiconductor package at various stages of manufacturing in accordance with some embodiments of the present technology.

FIG. 5 is a schematic view of a system that includes a semiconductor package configured in accordance with embodiments of the present technology.

The drawings have not necessarily been drawn to scale. Similarly, some components and/or operations can be separated into different blocks or combined into a single block for the purpose of discussion of some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

### Overview

Systems and methods for reducing (or eliminating) voids and/or gaps in encapsulants surrounding surface mount devices in semiconductor packages are disclosed herein. For example, the methods disclosed herein include encasing (e.g., fully covering) the surface mount devices with a fine filler encapsulant. The fine filler encapsulant can have a relatively small individual particle size, such as an individual particle size that is equal to or less than about 5 micrometers (μm). The relatively small particle size allows the fine filler encapsulant to fill small spaces between the surface mount devices and other components of the semiconductor packages and/or better adhere to exterior surfaces of the surface mount devices. As a result, as discussed in more detail below, the fine filler encapsulant can help eliminate voids and/or gaps around the surface mount devices, thereby reducing (or eliminating) various deleterious effects associated with the voids and/or gaps. Additional details on the semiconductor packages that incorporate the fine filler material, as well as related systems and methods, are set out below.

For ease of reference, the semiconductor packages, and components thereof, are sometimes described herein with reference to top and bottom, upper and lower, upwards and downwards, and/or horizontal plane, x-y plane, vertical, or z-direction relative to the spatial orientation of the embodiments shown in the figures. It is to be understood, however, that the semiconductor packages, and components thereof, can be moved to, and used in, different spatial orientations without changing the structure and/or function of the disclosed embodiments of the present technology.

Further, although primarily discussed herein in the context of encasing a capacitor, one of skill in the art will understand that the scope of the technology is not so limited. For example, the fine filler material can be employed to encase a variety of other surface mount devices and/or other semiconductor package components where mold voids and/or delamination detrimentally affect the semiconductor package. Accordingly, the scope of the invention is not confined to any subset of embodiments, and is confined only by the limitations set out in the appended claims.

Specific details of several embodiments of semiconductor wafers, singulation thereof, and associated systems and methods are described below. The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or an assembly or other structure at various stages of processing before becoming a finished functional device. Depending upon the context in which it is used, the term “substrate” can refer to a wafer-level substrate or a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or the die level.

Further, unless the context indicates otherwise, structures disclosed herein can be formed using conventional semiconductor manufacturing techniques. Materials can be deposited, for example, using chemical vapor deposition (CVD), physical vapor deposition (PVD), atomic layer deposition (ALD), spin coating, plating, and/or other suitable techniques. Similarly, materials can be removed, for example, using plasma etching, wet etching, chemical-mechanical planarization, or other suitable techniques. Some of the techniques may be combined with photolithography processes.

High density of processing capabilities, high speed of processing power access, lower power consumption, and reduced chip and/or package size are features that are demanded from semiconductor memory. To meet these demands, semiconductor dies (e.g., logic dies, memory dies (such as DRAM dies, SRAM dies, and/or the like), interface dies, controller dies, processor dies, and/or the like) are often integrated with a base substrate (e.g., a printed circuit board and/or other package substrate) adjacent to one or more surface-mount devices. The surface mount devices can help support the operation of the dies on the base substrate and/or the operation of various other semiconductor devices integrated with the base substrate. Purely by way of example, the surface-mount devices can include capacitors, resistors, inductors, discrete semiconductors (e.g., discrete diodes, transistors, and/or the like), and/or the like. Surface-mount devices allow a relatively large number of components to be densely packed onto the base substrate, thereby increasing the processing capabilities and/or processing power available on the base substrate.

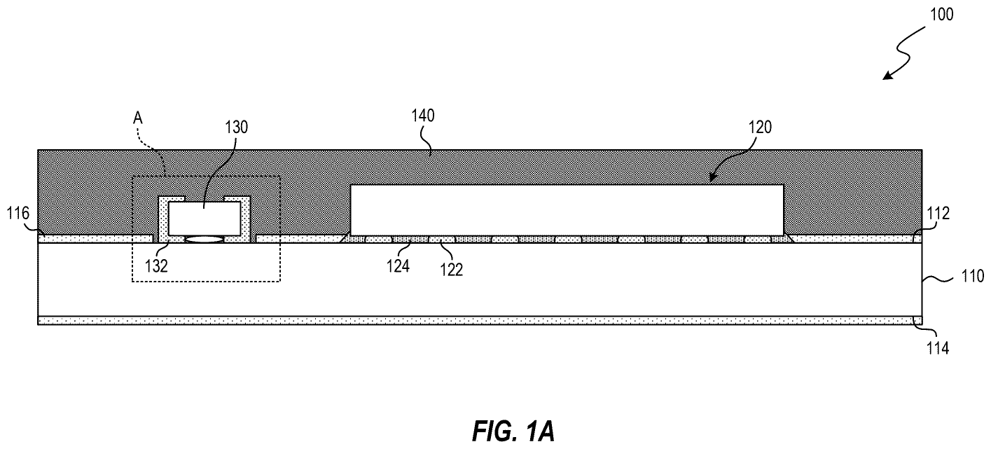

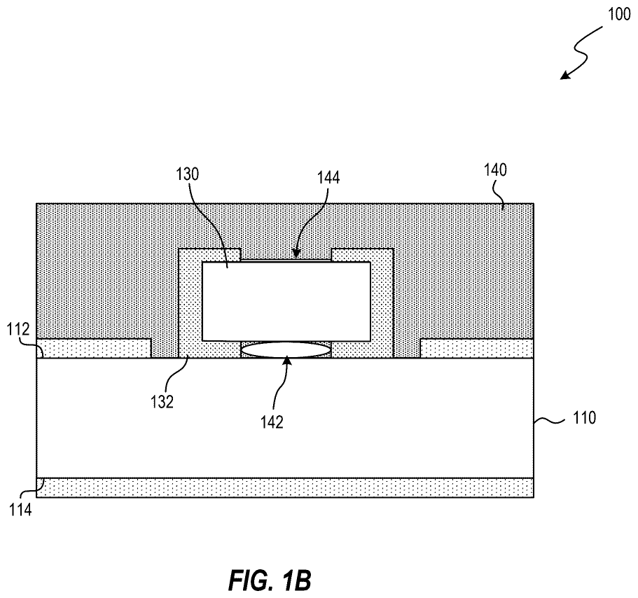

FIGS. 1A is a partially schematic cross-sectional view of an example of a semiconductor package 100 and FIG. 1B is a partially schematic cross-sectional blown-up view of a region A of the semiconductor package 100 illustrated in FIG. 1A. As illustrated in FIG. 1A, the semiconductor package 100 includes a base substrate 110, as well as one or more semiconductor dies 120 (one illustrated in FIG. 1A) and one or more capacitors 130 (one illustrated in FIG. 1A) each integrated with an upper surface 112 of the base substrate 110.

The base substrate 110 can be a printed circuit board (PCB), another prepreg substrate, an interposer (e.g., a silicon interposer), and/or any other suitable substrate. Further, as illustrated in FIG. 1A, the upper surface 112 and a lower surface 114 of the base substrate 110 can be at least partially coated in a dielectric layer 116 to insulate the base substrate 110. Although not illustrated in FIG. 1A, one of skill in the art will understand that the upper surface 112 can include a plurality of bond sites (e.g., bond pads), route lines, and/or redistribution layers formed thereon. Purely by way of example, the upper surface 112 can include route lines between the semiconductor die 120 and the capacitor 130 to electrically couple the semiconductor components. Further, one of skill in the art will understand that the base substrate can include one or more interconnects and/or metallization layers between the upper surface 112 and the lower surface 114 to establish various communication channels through the base substrate 110.

The semiconductor die 120 and the capacitor 130 are each integrated with (e.g., carried by and electrically coupled to) the upper surface 112 through openings in the dielectric layer 116. For example, as illustrated in FIG. 1A, the semiconductor die 120 can be integrated with (e.g., carried by and electrically coupled to) the upper surface 112 by one or more solder structures 122 (e.g., solder balls and/or the like) between the semiconductor die and a capillary underfill material 124 surrounding the solder structures 122. Similarly, the capacitor 130 is also integrated with the upper surface 112 by solder structures 132 (e.g., solder films, solder balls, and/or the like) on opposing sides of the capacitor 130.

As further illustrated in FIG. 1A, the semiconductor package 100 also includes an encapsulant 140 encasing the semiconductor die 120, the capacitor 130, and the upper surface 112 of the base substrate 110. The encapsulant 140 can insulate and protect the semiconductor die 120, the capacitor 130, and the upper surface 112 during later packaging processes and/or during operation of the semiconductor package 100. For example, the encapsulant 140 can help prevent the solder structures 132 around the capacitor from bridging on an upper surface of the capacitor 130.

However, it can be difficult to fully encase the components of the semiconductor package 100 with the encapsulant. For example, as best illustrated in FIG. 1B, a deposition process for the encapsulant 140 can result in a void 142 between the capacitor 130 and the base substrate 110. The void 142 traps atmospheric gasses beneath the capacitor 130 that has several deleterious effects on the semiconductor package 100. For example, the void 142 gasses in the void can expand and contract in response to changes in temperature (e.g., due to reflow processes during packaging, operation of the semiconductor package 100, and/or the like). The expansions and contractions can push the capacitor 130 away from the base substrate 110, thereby threatening to delaminate the capacitor 130. Further, the forces can be transferred to the encapsulant 140, thereby pushing the encapsulant away from the base substrate 110 and/or the semiconductor die 120 (FIG. 1A) and causing further delamination issues. Additionally, or alternatively, the expansions and contractions can warp the base substrate 110 to create bulges on the lower surface 114 opposite the capacitor 130 (sometimes referred to as a “popcorn problem”). The bulges, in turn, can undermine bonds formed with the lower surface of the base substrate 110 and/or prevent the base substrate 110 from being bonded to another substrate (e.g., to another semiconductor package, a PCB, motherboard, and/or the like). Further, the void 142 can provide space for the solder structures 132 around the capacitor 130 to flow into, creating a risk of solder bridging beneath the capacitor 130 during high temperature manufacturing process and/or operation of the semiconductor package 100.

As further illustrated in FIG. 1B, the encapsulant 140 can have a relatively poor adherence to the capacitor 130, which can result in one or more gaps 144 (one illustrated in FIG. 1B) around exterior surfaces of the capacitor 130. Similar to the void 142, the gap 144 can cause delamination between the capacitor 130 and the encapsulant, creating an overall delamination problem for the semiconductor package 100. Further, the gap 144 can provide space for the solder structures 132 to bridge on top of the capacitor 130 during later reflow and other high temperature packaging processes and/or during operation of the semiconductor package 100. Said another way, poor adherence between the encapsulant 140 and the capacitor 130 (and/or other components of the semiconductor package 100) can undermine the packaging processes and/or reduce a lifespan of the semiconductor package 100.

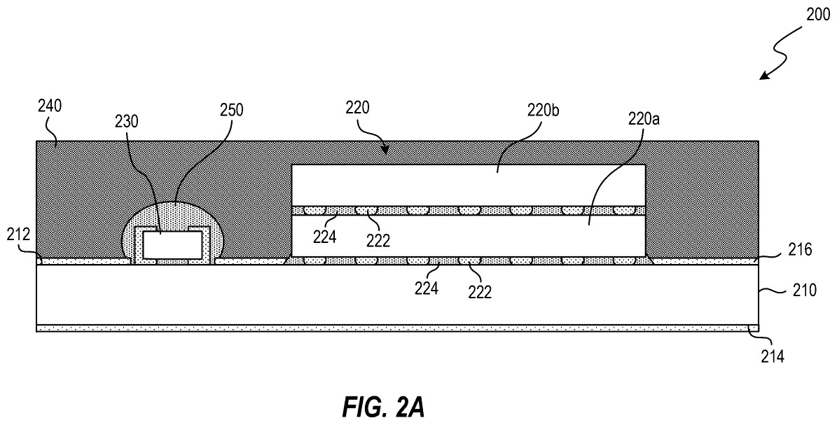

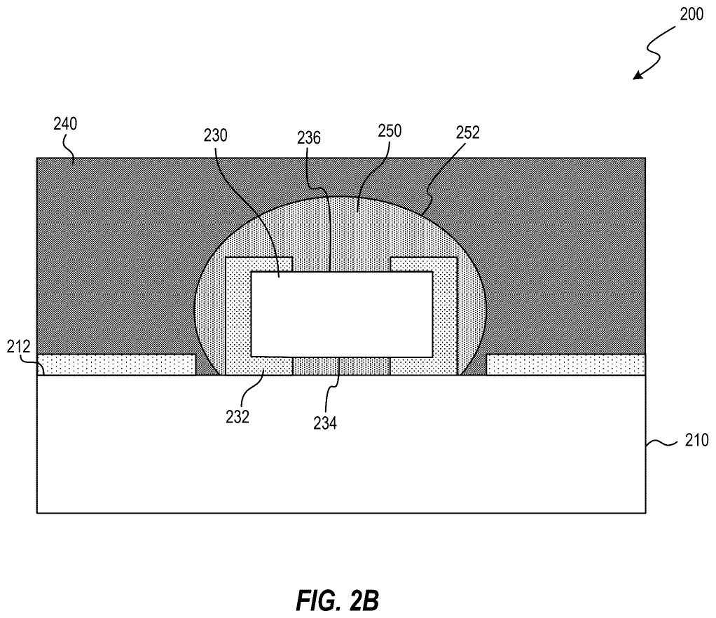

Systems and methods for addressing the shortcomings discussed above are disclosed herein. For example, the methods disclosed herein can include integrating one or more capacitors and one or more semiconductor dies with an upper surface of a base substrate of the semiconductor package; encasing each of the one or more capacitors with a first encapsulant; then depositing a second encapsulant over each of the one or more capacitors and the die stack. The first encapsulant (sometimes referred to herein as a “fine filler encapsulant” and/or the like) can have a first individual particle size that is smaller than a second individual particle size of the second encapsulant (sometimes referred to herein as a “packaging encapsulant” and/or the like). The relatively small particle size allows the first encapsulant to completely fill spaces between the capacitors and the base substrate and/or fully adhere to the surfaces of the capacitors. As a result, the first encapsulant can reduce (or eliminate) the voids and/or gaps around the capacitors that can cause delamination, solder bridging, and/or damage to the package substrate during reflow processes and/or operation of the semiconductor device. Additionally, or alternatively, the first encapsulant can act as an intermediate layer between the capacitors and the second encapsulant to improve adhesion within the semiconductor package and/or to help reduce the chance of delamination in the semiconductor package. As discussed in more detail below, the first encapsulant can have an individual particle size that is less than or equal to about 5 micrometers. In a specific, non-limiting example, the first encapsulant can be (or include) a capillary underfill material, such as the capillary underfill material used to prevent solder bridging beneath the semiconductor die. In some such embodiments, the process of manufacturing the semiconductor package adapts a dispensing process for the capillary underfill material to dispense the capillary underfill material over the capacitors. Additional details on semiconductor packages, and related systems and methods, are discussed below with reference to FIGS. 2A-5.

FIGS. 2A and 2B are partially schematic cross-sectional views of a semiconductor package 200 configured in accordance with some embodiments of the present technology. As illustrated in FIG. 2A, the semiconductor package 200 (sometimes also referred to herein as a “stacked semiconductor device,” “semiconductor assembly,” and/or the like) includes a base substrate 210 that has an upper surface 212 and a lower surface 214 opposite the upper surface 212. The semiconductor package 200 also includes one or more semiconductor dies 220 (two illustrated in FIG. 2A) and one or more capacitors 230 (one illustrated in FIG. 2A) each integrated with an upper surface 212 of the base substrate 210.

The base substrate 210 can be a PCB, another prepreg substrate, an interposer (e.g., a silicon interposer), and/or any other suitable substrate. Further, the upper surface 212 and the lower surface 214 of the base substrate 210 can be at least partially coated in a dielectric layer 216 to insulate the base substrate 210. Similar to the discussion above, although not illustrated in FIG. 2A, one of skill in the art will understand that the upper surface 212 can include a plurality of bond sites (e.g., bond pads), route lines, and/or redistribution layers formed thereon. Purely by way of example, the upper surface 212 can include a redistribution layer coupling the semiconductor dies 220 to the capacitor 230. Further, one of skill in the art will understand that the base substrate can include one or more interconnects and/or metallization layers between the upper surface 212 and the lower surface 214 to establish communication channels through the base substrate 210.

The semiconductor dies 220 and the capacitor 230 are each integrated with (e.g., carried by and electrically coupled to) the upper surface 212 through openings in the dielectric layer 216. For example, a lowermost die 220a from the semiconductor dies 220 can be integrated with the upper surface 212 by one or more solder structures 222 (e.g., solder balls and/or the like) between the lowermost die 220a and a capillary underfill material 224 surrounding the solder structures 222. Further, an uppermost die 220b from the semiconductor dies 220 can be integrated with the lowermost die 220a by one or more solder structures 222 and a capillary underfill material 224 surrounding the solder structures 222. Similarly, the capacitor 230 is also integrated with the upper surface 212 by solder structures 232 (e.g., solder films, solder balls, and/or the like) on opposing sides of the capacitor 230.

In some embodiments, the solder structures 222 are replaced by another interconnect structure (e.g., metal pillars, metal-metal bond pads, and/or the like). In such embodiments, the semiconductor package 200 can eliminate the capillary underfill material 224 around the solder structures 222. In a specific, non-limiting example, the semiconductor die can be integrated with the upper surface 212 of the base substrate 210 via a hybrid bonding scheme (e.g., substrate-substrate bonds and metal-metal bonds).

Similar to the discussion above, the semiconductor package 200 can also include a package encapsulant 240 encasing the semiconductor dies 220, the capacitor 230, and the upper surface 212 of the base substrate 210. The package encapsulant 240 (sometimes also referred to herein as a “second encapsulant,” a “package mold material,” and/or the like) can insulate and protect semiconductor dies 220, the capacitor 230, and the upper surface 212 during later packaging processes and/or during operation of the semiconductor package 200. However, as illustrated in FIG. 2A, the semiconductor package 200 can also include a fine filler encapsulant 250 encasing the capacitor 230.

The fine filler encapsulant 250 can be a fine filler encapsulant (sometimes also referred to as a “first encapsulant,” a “small particle filler,” and/or the like) with an individual particle size that is equal to or less than about 5 micrometers (μm). In a specific, non-limiting example, the second encapsulant can include a capillary underfill material that is generally similar to (or the same as) the capillary underfill material 224 (FIG. 2A) surrounding the solder structures 222 integrating the semiconductor dies 220 to the upper surface 212. In such embodiments, as discussed in more detail below, the packaging process for the semiconductor package 200 can be modified to deposit a large volume of the capillary underfill material around the capacitor 230 (e.g., enough to fully encase the capacitor 230) while integrating the semiconductor dies 220 (FIG. 2A) with the upper surface. The individual particle size of less than or equal to 5 μm is significantly smaller than the particle size for typical epoxies and mold materials in semiconductor packages (e.g., the particle size of the package encapsulant 240). The relatively small particle size allows the fine filler encapsulant 250 to better flow around the capacitor 230 and/or to have a better adhesion to the surface of the capacitor 230 as compared to the package encapsulant 240. As a result, the fine filler encapsulant 250 can help reduce (or eliminate) the problems discussed above with reference to FIGS. 1A and 1B.

For example, as best illustrated in the blown-up view of the capacitor 230 illustrated in FIG. 2B, the fine filler encapsulant 250 can completely fill a space between a lower surface 234 of the capacitor 230 and the upper surface 212 of the base substrate 210. As a result, the fine filler encapsulant 250 can eliminate (or reduce) the void 142 discussed above with reference to FIG. 1B. By eliminating (or reducing) the void between the capacitor 230 and the upper surface 212, the fine filler encapsulant 250 can help reduce delamination in the semiconductor package 200, popcorn problems in the base substrate 210, and/or solder bridging along the lower surface 234. Additionally, or alternatively, the fine filler encapsulant 250 can better adhere to an upper surface 236 of the capacitor 230. As a result, the fine filler encapsulant 250 can eliminate (or reduce) the gap 144 discussed above with reference to FIG. 1B. By eliminating (or reducing) the gaps between the upper surface 236 and the fine filler encapsulant 250, the fine filler encapsulant 250 can help reduce delamination in the semiconductor package 200 and/or bridging along the upper surface 236. Still further, the fine filler encapsulant 250 can bond relatively well with the package encapsulant 240 (e.g., without any voids, with relatively high surface adhesion, and/or the like). As a result, the fine filler encapsulant 250 can act as an intermediary encapsulant between the capacitor 230 and the package encapsulant 240, improving overall adhesion within the semiconductor package 200.

As further illustrated in FIG. 2B, the fine filler encapsulant 250 can have a generally curved outer surface 252. The curved outer surface 252 can result from a wetting effect caused by the relatively small particle size of the second encapsulant, resulting in an ovular profile for the fine filler encapsulant 250 in the semiconductor package 200. The curved profile, in turn, can help ensure that each surface of the capacitor 230 is fully encased to maximize the benefits of incorporating the fine filler encapsulant 250 in the semiconductor package 200.

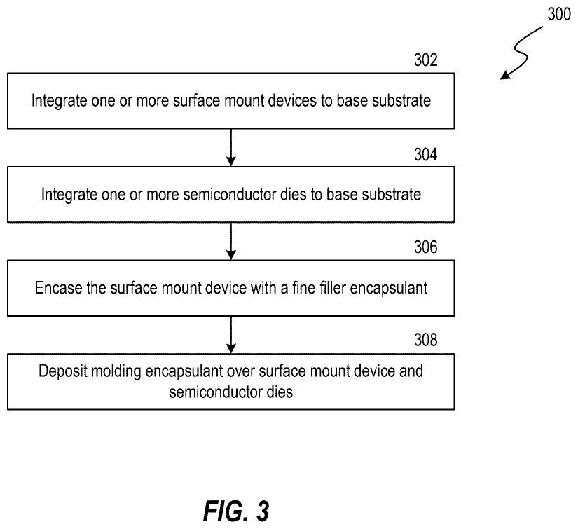

FIG. 3 is a flow diagram of a process 300 for manufacturing a semiconductor package in accordance with some embodiments of the present technology. One or more manufacturing apparatuses can execute the process 300 to produce a semiconductor package generally similar to (or the same as) the semiconductor package 200 discussed above with reference to FIGS. 2A and 2B. Accordingly, the process 300 is discussed below with frequent reference to FIGS. 2A and 2B. However, one of skill in the art will understand that the process 300 is not so limited. Purely by way of example, the process 300 can produce semiconductor packages with various additional (or alternative) surface mount devices as compared to the capacitor 230 discussed above with reference to FIGS. 2A and 2B. In a specific, non-limiting example, the additional (or alternative) surface mount devices can include one or more resistors, inductors, discrete semiconductors (e.g., discrete diodes, transistors, and/or the like), and/or the like.

Further, although the process 300 is described herein with reference to a single semiconductor package, it will be understood that the process 300 can be executed at a wafer level to manufacture multiple semiconductor packages at the same time. In such embodiments, each of the steps of the process discussed below can be completed for each of the semiconductor packages on the wafer before moving to the next step. Alternatively, different steps of the process 300 can be completed for different semiconductor packages generally simultaneously (e.g., completing block 304 for a first semiconductor package while completing block 302 for a second semiconductor package).

The process 300 begins at block 302 by integrating (e.g., physically and electrically coupling) one or more surface mount devices (e.g., the capacitor 230 of FIG. 2A) to a base substrate (e.g., the upper surface 212 of the base substrate 210 of FIG. 2A). The process 300 at block 302 can integrate the surface mount device(s) to the base substrate by stacking the surface mount device(s) on the base substrate, then heating the semiconductor package to reflow one or more solder structures on each of the surface mount device(s) (e.g., the solder structures 232 of FIG. 2A).

At block 304, the process 300 includes integrating one or more semiconductor dies (e.g., the semiconductor dies 220 of FIG. 2A) to the base substrate. In some embodiments, the process 300 at block 304 includes stacking the semiconductor die(s) on the base substrate, depositing a capillary underfill material (e.g., the capillary underfill material 224) around interfacing surfaces (e.g., between the lowermost die 220a and the base substrate 210 of FIG. 2A, between the lowermost die 220a and the uppermost die 220b of FIG. 2A, and the like), then heating the semiconductor package to reflow one or more solder structures on each of the semiconductor dies (e.g., the solder structures 222 of FIG. 2A). The deposition of the capillary underfill material can be accomplished using a dispensing needle that moves in a longitudinal direction over the semiconductor package (e.g., within an x-y plane above the base substrate) while dispensing the capillary underfill material. The capillary underfill material can fill spaces between solder structures at the interfacing surfaces. As a result, when the semiconductor package is heated, the capillary underfill material can help prevent the solder structures from bridging and creating shorts in the semiconductor package. Additionally, or alternatively, the capillary underfill material can help eliminate voids between the interfacing surfaces.

In some embodiments, the process 300 at block 304 includes stacking the semiconductor die(s) on the base substrate and then heating and/or applying pressure to the semiconductor die to form a hybrid bond (e.g., a substrate-substrate bond and a metal-metal bond) between the semiconductor die and the base substrate. In such embodiments, the process 300 does not need to dispense a capillary underfill material around the semiconductor dies.

At block 306, the process 300 includes encasing (e.g., fully surrounding) the surface mount device(s) with a fine filler encapsulant (e.g., the fine filler encapsulant 250 of FIGS. 2A and 2B). As discussed above, the fine filler encapsulant can have an individual particle size that is less than or equal to about 5 μm. As also discussed above, the relatively small particle size can help ensure that the fine filler encapsulant is able to better flow around the surface mount device(s), particularly when placed in close proximity to the semiconductor die(s) and/or other semiconductor components. Additionally, or alternatively, the relatively small particle size can help ensure that the fine filler encapsulant adheres to the surface of the surface mount device(s). The process 300 at block 306 can dispense the fine filler encapsulant from a dispensing needle generally similar to (or the same as) the dispensing needle used to dispense the capillary underfill material. In some such embodiments, the dispensing needle is positioned over an individual surface mount device and then held in place while encasing the individual surface mount device. In other such embodiments, the dispensing needle is positioned over an individual surface mount device, then moved in a vertical direction (e.g., generally perpendicular to the longitudinal direction and/or along a z-axis) while encasing the individual surface mount device.

In some embodiments, the process 300 completes block 306 before completing block 304 to encase the surface mount device(s) with the fine filler encapsulant before integrating the semiconductor die(s) with the base substrate. In some embodiments, the process 300 completes block 306 generally simultaneously with block 304. For example, when the fine filler encapsulant is the capillary underfill material deposited around the semiconductor die(s), the deposition process can include two sub-processes. The first can deposit the capillary underfill material around the semiconductor die(s) while the second can deposit the capillary underfill material over the surface mount device(s). In various such embodiments, the process 300 can encase the surface mount device(s) with the capillary underfill material before or after depositing the capillary underfill material around the semiconductor die(s). Further, in various embodiments, the second sub-process can include holding the dispensing needle in place over each of the surface mount device(s) and/or moving the dispensing needle along a vertical motion path over each of the surface mount device(s).

At block 308, the process 300 includes depositing a package encapsulant (e.g., the package encapsulant 240 of FIG. 2A) over the surface mount device(s) and the semiconductor die(s). The package encapsulant can help insulate and/or otherwise protect the surface mount device(s) and the semiconductor die(s) in future packaging processes and/or during operation in part of an electronic device. Because the package encapsulant does not need to flow into small spaces around any of the surface mount device(s) and the semiconductor die(s), the package encapsulant can have a relatively large particle size (e.g., between about 10 μm and about 55 μm). The process 300 at block 308 can include injecting the package encapsulant using a molding needle, flowing the package encapsulant around the semiconductor package using a mold chase, and/or any other suitable process.

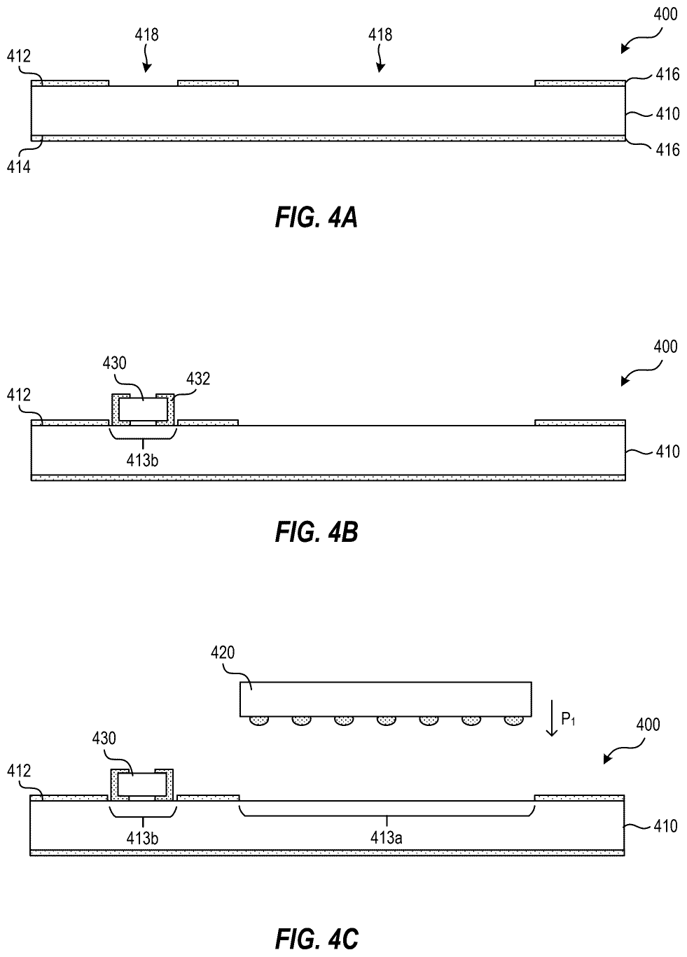

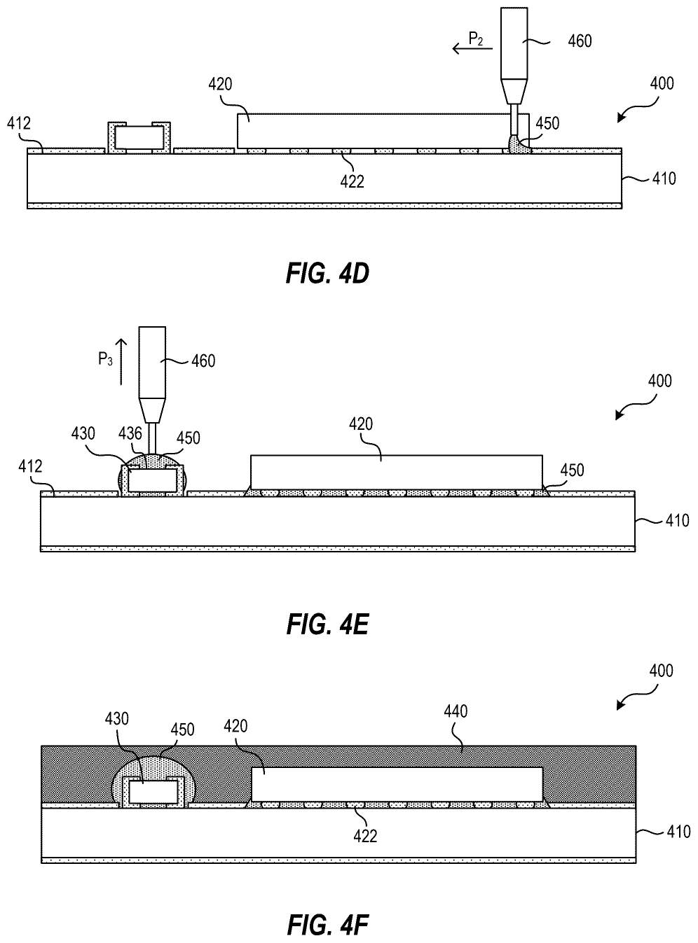

FIGS. 4A-4F are partially schematic cross-sectional views of a semiconductor package 400 at various stages of manufacturing in accordance with some embodiments of the present technology. The manufacturing process illustrated in FIGS. 4A-4F is generally similar to a specific subset of embodiments of the process 300 discussed above with reference to FIG. 3 that use a capillary underfill material as the fine filler encapsulant around the surface mount devices.

FIG. 4A illustrates the semiconductor package 400 after forming a dielectric layer 416 on an upper surface 412 and a lower surface 414 of a base substrate 410. As discussed above, the base substrate 410 can be a PCB, another prepreg substrate, an interposer substrate (e.g., a silicon interposer), and/or any other suitable substrate. As further illustrated in FIG. 4A, the dielectric layer 416 on the upper surface 412 is formed with two or more openings 418 (two illustrated in FIG. 4A) generally corresponding to mounting locations for surface mount devices and semiconductor dies for the semiconductor package 400. That is, the openings 418 expose portions of the upper surface 412 to allow the surface mount devices and semiconductor dies to be integrated thereon.

For example, FIG. 4B illustrates the semiconductor package 400 after a capacitor 430 has been integrated with the base substrate 410. To integrate the capacitor 430 with the base substrate 410, the capacitor 430 is stacked on a secondary-attach region 413b of the upper surface 412. Then, the semiconductor package 400 (or components thereof) is heated to reflow solder structures 432 on opposing sides of the capacitor 430. The solder structures 432 (e.g., solder films, solder balls, and/or the like) can then form an electrical and physical bond between the capacitor 430 and the secondary-attach region 413b (sometimes also referred to herein as a “surface mount region,” a “capacitor-attach region,” a “passive device region,” and/or the like) of the upper surface 412.

FIG. 4C illustrates the semiconductor package 400 while stacking a semiconductor die 420 on the base substrate 410. As illustrated in FIG. 4C, the stacking process can include aligning the semiconductor die 420 with a primary-attach region 413a of the upper surface 412, then moving the semiconductor die 420 along a first motion path PI toward the upper surface 412. As illustrated in FIG. 4C, the primary-attach region 413a (sometimes also referred to herein as an “active device region,” a “die-attach region,” and/or the like) can be positioned adjacent to the secondary-attach region 413b. As a result, the semiconductor die 420 is stacked on the upper surface adjacent to the capacitor 430.

FIG. 4D illustrates the semiconductor package 400 while depositing a capillary underfill material 450 around the semiconductor die 420. During the deposition process, a dispensing component 460 (e.g., a dispensing needle and/or another suitable component) can move along a second motion path P₂ while dispensing the capillary underfill material 450. As illustrated in FIG. 4D, the second motion path P₂ can be a generally horizontal motion path (e.g., generally parallel to an x-y plane through the base substrate 410) that at least partially traces a perimeter of the semiconductor die 420. As the capillary underfill material 450 is dispensed, at least a portion of the capillary underfill material 450 can flow between the semiconductor die 420 and the upper surface 412 of the base substrate 410. As a result, the capillary underfill material 450 can surround solder structures (e.g., solder balls) between the semiconductor die 420 and the upper surface 412 to help insulate the and/or control the solder structures 422 during later reflow processes. Once the capillary underfill material 450 has been deposited, the solder structures 422 can be reflowed to integrate (e.g., physically and electrically couple) the semiconductor die 420 to the base substrate 410.

In some embodiments, as discussed above, the semiconductor package 400 includes one or more additional semiconductor dies stacked on the semiconductor die 420 (e.g., the uppermost die 220b of FIG. 2A). In some such embodiments, the manufacturing process can stack each of the dies on the primary-attach region 413a (FIG. 4C) before depositing the capillary underfill material 450. In some embodiments, the semiconductor dies can be stacked and surrounded by the capillary underfill material 450 sequentially (e.g., first stack and surround a lowermost die with the capillary underfill material 450, then stack a surround a second die with the capillary underfill material 450, and so on).

FIG. 4E illustrates the semiconductor package 400 after depositing the capillary underfill material 450 fully around the semiconductor die 420 and while depositing the capillary underfill material 450 over the capacitor 430. The deposition process can include positioning the dispensing component 460 over an upper surface 436 of the capacitor 430, then moving the dispensing component 460 along a third motion path P₃. As illustrated in FIG. 4E, the third motion path P₃ can be a generally vertical motion path that is orthogonal to the second motion path P₂. For example, while moving along the third motion path P₃, the dispensing component 460 can begin close to the capacitor 430, then travel vertically away from the capacitor 430 as the capillary underfill material 450 builds up. The deposition directly over the upper surface 436 can allow the capillary underfill material 450 to flow around the capacitor 430 to fill a space between the capacitor 430 and the upper surface 412 and/or to adhere to each of the surfaces of the capacitor 430. As a result, as discussed above with reference to FIG. 2B, the capillary underfill material 450 can help eliminate voids between the capacitor 430 and the base substrate 410, reduce delamination, and reduce the chance of solder bridging on each surface of the capacitor 430. As further illustrated in FIG. 4E, a wetting effect in the capillary underfill material 450 can cause the capillary underfill material 450 to have a generally curved profile as it flows around and builds up over the capacitor 430.

FIG. 4F the semiconductor package 400 after depositing a package encapsulant 440 over the semiconductor package 400. As a result, the package encapsulant surrounds, insulates, and/or protects the semiconductor die 420, the capacitor 430, and the upper surface 412 of the base substrate 410. As discussed above, the process for depositing the package encapsulant can include another dispensing component, a mold chase, and/or any other suitable components. In embodiments where the semiconductor package 400 is formed at the wafer level, the semiconductor package can then be singulated from other packages (e.g., via blade dicing, chemical etching, laser ablation, and/or the like).

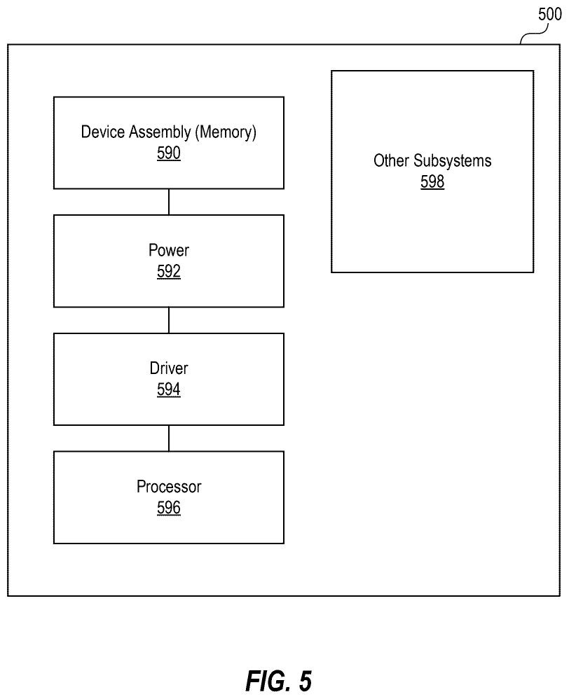

FIG. 5 is a schematic view of a system that includes a semiconductor package configured in accordance with embodiments of the present technology. That is, the semiconductor packages discussed above can be incorporated into any of a myriad of larger and/or more complex systems, a representative example of which is system 500 shown schematically in FIG. 5. The system 500 can include a memory 590 (e.g., SRAM, DRAM, flash, and/or other memory devices), a power supply 592, a drive 594, a processor 596, and/or other subsystems or components 598. Semiconductor packages of the type discussed above with reference to FIGS. 2A and 2B and/or manufactured using processes of the type discussed above with reference to FIGS. 3-4F can be included in any of the elements shown in FIG. 5. Purely by way of example, the semiconductor package 200 of FIG. 2A can be deployed in the memory 590 (e.g., in a managed NAND for use in various consumer electronics, automotive electronics, and the like; an SSD package; and/or any other suitable memory device).

The resulting system 500 can be configured to perform any of a wide variety of suitable computing, processing, storage, sensing, imaging, and/or other functions. Accordingly, representative examples of the system 500 include, without limitation, computers and/or other data processors, such as desktop computers, laptop computers, Internet appliances, hand-held devices (e.g., palm-top computers, wearable computers, cellular or mobile phones, automotive electronics, personal digital assistants, music players, etc.), tablets, multi-processor systems, processor-based or programmable consumer electronics, network computers, and minicomputers. Additional representative examples of the system 500 include lights, cameras, vehicles, etc. With regard to these and other examples, the system 500 can be housed in a single unit or distributed over multiple interconnected units, e.g., through a communication network. The components of the system 500 can accordingly include local and/or remote memory storage devices and any of a wide variety of suitable computer-readable media.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A method for manufacturing a semiconductor package, the method comprising:
integrating one or more capacitors with an upper surface of a base substrate of the semiconductor package;
integrating a die stack of one or more semiconductor dies with the upper surface of the base substrate;
encasing each of the one or more capacitors with a first encapsulant, wherein the first encapsulant has a first individual particle size; and
depositing a second encapsulant over each of the one or more capacitors and the die stack, wherein the second encapsulant has a second individual particle size larger than the first individual particle size.

2. The method of claim 1 wherein encasing each of the one or more capacitors with the first encapsulant comprises, for each individual capacitor:
positioning a dispensing component over the individual capacitor; and
dispensing a volume of the first encapsulant sufficient to fully cover each surface of the individual capacitor with the first encapsulant.

3. The method of claim 1 wherein the first encapsulant has a particle size of less than about 5 micrometers.

4. The method of claim 1 wherein encasing each of the one or more capacitors with the first encapsulant comprises, for each individual capacitor, filling a space between a lower surface of the individual capacitor and the upper surface of the base substrate with the first encapsulant.

5. The method of claim 1 wherein encasing each of the one or more capacitors with the first encapsulant comprises, for each individual capacitor, dispensing the first encapsulant over an upper surface of the individual capacitor to adhere the first encapsulant to the upper surface of the individual capacitor.

6. The method of claim 1 wherein the first encapsulant is a capillary underfill material, and wherein encasing each of the one or more capacitors with a first encapsulant comprises, for each individual capacitor:
positioning a dispensing needle over an upper surface of the individual capacitor; and
moving the dispensing needle in a vertical direction while dispensing the capillary underfill material over the upper surface of the individual capacitor.

7. A semiconductor package, comprising:
a base substrate;
a stack of one or more dies integrated with a die-attach region of an upper surface of the base substrate;
a surface mount device integrated with a passive device region of the upper surface of the base substrate;
a first encapsulant material encasing the surface mount device; and
a second encapsulant material encasing the surface mount device and the stack of one or more dies, wherein the second encapsulant material is different from the first encapsulant material.

8. The semiconductor package of claim 7 wherein the first encapsulant material has a first particle size, and wherein the second encapsulant material has a second particle size larger than the first particle size.

9. The semiconductor package of claim 8 wherein the first particle size is less than about 5 micrometers.

10. The semiconductor package of claim 7 wherein the first encapsulant material comprises a capillary underfill material.

11. The semiconductor package of claim 10 wherein the stack of one or more dies includes a lowermost die, wherein the first encapsulant material comprises a first volume of the capillary underfill material, and wherein the semiconductor package further comprises a second volume of the capillary underfill material between the lowermost die and the base substrate.

12. The semiconductor package of claim 7 wherein the first encapsulant material has a curved outer profile.

13. The semiconductor package of claim 7 wherein the first encapsulant material is configured to prevent solder bridging on an upper surface of the surface mount device.

14. The semiconductor package of claim 7 wherein the first encapsulant material is configured to prevent voids from forming between the surface mount device and the base substrate.

15. A method for manufacturing a semiconductor package, comprising:
integrating a surface mount device with an upper surface of a base substrate of the semiconductor package;
integrating one or more semiconductor dies with the upper surface of the base substrate adjacent to the surface mount device;
depositing a fine filler encapsulant over the surface mount device to encase the surface mount device in the fine filler encapsulant, wherein depositing the fine filler encapsulant includes filling a gap between the surface mount device and the upper surface of the base substrate with the fine filler encapsulant; and
depositing a package encapsulant over the surface mount device and the one or more semiconductor dies.

16. The method of claim 15 wherein the fine filler encapsulant has an individual particle size of less than about 5 micrometers.

17. The method of claim 15 wherein the fine filler encapsulant is a capillary underfill material, and wherein depositing the fine filler encapsulant over the surface mount device includes positioning a dispensing needle over the surface mount device to dispense the capillary underfill material over a top surface of the surface mount device.

18. The method of claim 17 wherein integrating the one or more semiconductor dies with the upper surface of the base substrate includes dispensing the capillary underfill material around the one or more semiconductor dies using the dispensing needle.

19. The method of claim 18 wherein dispensing the capillary underfill material around the one or more semiconductor dies includes moving the dispensing needle along a horizontal motion path, and wherein depositing the fine filler encapsulant over the surface mount device includes positioning the dispensing needle over the surface mount device.

20. The method of claim 18 wherein dispensing the capillary underfill material around the one or more semiconductor dies includes moving the dispensing needle along a first motion path, and wherein depositing the fine filler encapsulant over the surface mount device includes moving the dispensing needle along a second motion path orthogonal to the first motion path.
